(19) United States
(12) Patent Application Publication
(10) Pub. No.: US 2026/0121125 A1
(43) Pub. Date: Apr. 30, 2026

(54) FORMATION CONTROL METHOD FOR LITHIUM-ION BATTERY AND FORMATION SYSTEM

(71) Applicant: ZHEJIANG JINKO ENERGY STORAGE CO., LTD., Haining (CN)

(72) Inventors: Yutao SHI, Haining (CN); Yujun MA, Haining (CN); Zixiang YANG, Haining (CN)

(21) Appl. No.: 18/949,169

(22) Filed: Nov. 15, 2024

(30) Foreign Application Priority Data
Oct. 31, 2024 (CN) 202411547427.3

(51) Int. Cl. H01M 10/058; G01R 31/367; G01R 31/378; G01R 31/385; H01M 10/42; H01M 10/48

(52) U.S. Cl. CPC H01M 10/058; G01R 31/367; G01R 31/378; G01R 31/3865; H01M 10/4235; H01M 10/486

(57) ABSTRACT

A formation control method and a formation system for a lithium-ion battery are disclosed. The method includes: acquiring an actual process parameter of the lithium-ion battery in a formation process and first data sets of a plurality of historical formation processes; determining a reference range of delithiation effect characteristics of the lithium replenishing additive based on the plurality of first data sets; predicting a delithiation effect characteristic quantity of the lithium replenishing additive in the formation process based on the actual process parameter; determining a deviation of the delithiation effect characteristic quantity from the reference range based on the delithiation effect characteristic quantity and the reference range; and determining, when the deviation is greater than a preset threshold, a to-be-adjusted parameter and an adjustment priority of the to-be-adjusted parameter based on the deviation, and adjusting the formation process based on the to-be-adjusted parameter and the adjustment priority.

### CROSS-REFERENCE TO RELATED APPLICATIONS

The present application claims priority to Chinese patent application No. 202411547427.3, filed on Oct. 31, 2024, the entire contents of which are incorporated herein by reference.

### TECHNICAL FIELD

The present disclosure relates to the field of lithium-ion battery formation, and in particular, to a formation control method and a formation system for a lithium-ion battery.

### BACKGROUND

A conventional lithium-ion battery formation process includes a solid electrolyte interphase (SEI) film formation stage and a lithium replenishing agent delithiation stage. In the SEI film formation stage, a low voltage is used, and a process for cells without lithium replenishment is adopted. In the lithium replenishing agent delithiation stage, a high voltage is used, and a battery is charged to a lithium replenishing agent delithiation voltage by using 2 to 3 stages of current reduction steps.

During mass production from powder feeding to conversion into cells, due to differences in material batches, differences in distribution of a lithium replenishing agent, and accumulation of dimensional tolerances, there are performance differences between cells, and the conventional formation process cannot adapt to the differences between the cells, resulting in differences in a lithium replenishing agent delithiation effect of the battery during the formation, thereby exacerbating inconsistency of performance of the cells.

### SUMMARY

According to one aspect of the present disclosure, a formation control method for a lithium-ion battery is provided, including: acquiring an actual process parameter of the lithium-ion battery in a formation process and first data sets of a plurality of historical formation processes, the first data set of each of the plurality of historical formation processes including formation gas production rate change data of the historical formation process, a gram capacity exertion of a lithium replenishing additive upon completion of formation, and a historical delithiation effect characteristic quantity; determining a reference range of delithiation effect characteristics of the lithium replenishing additive based on the plurality of first data sets, the delithiation effect characteristics being used to describe a delithiation effect; predicting a delithiation effect characteristic quantity of the lithium replenishing additive in the formation process based on the actual process parameter, the delithiation effect characteristic quantity being characteristic values of the delithiation effect characteristics; determining a deviation of the delithiation effect characteristic quantity from the reference range based on the delithiation effect characteristic quantity and the reference range; and determining, when the deviation is greater than a preset threshold, a to-be-adjusted parameter and an adjustment priority of the to-be-adjusted parameter based on the deviation, and adjusting the formation process based on the to-be-adjusted parameter and the adjustment priority, so that the deviation corresponding to the delithiation effect characteristic quantity after the adjustment is less than or equal to the preset threshold, the to-be-adjusted parameter being the actual process parameter to be adjusted.

Optionally, the first data set includes the formation gas production rate change data corresponding to a plurality of historical time nodes in the historical formation process, the gram capacity exertion corresponding to the historical formation process, and historical delithiation effect characteristic quantities corresponding to the plurality of historical time nodes, the plurality of historical time nodes being nodes representing process progress of the corresponding historical formation processes, and determining the reference range of delithiation effect characteristics of the lithium replenishing additive based on the plurality of first data sets includes: selecting at least one of the historical delithiation effect characteristic quantities corresponding to a first target parameter value at each of the historical time nodes from the plurality of first data sets as a preliminary historical delithiation effect characteristic quantity, the first target parameter value being one of a minimum formation gas production rate change data and a maximum gram capacity exertion; and determining the preliminary historical delithiation effect characteristic quantity corresponding to a second target parameter value at each of the historical time nodes to be a delithiation effect reference value, and obtaining the reference range representing variations of the delithiation effect reference value over time, the second target parameter value being the other of the minimum formation gas production rate change data and the maximum gram capacity exertion, the delithiation effect reference value being a reference value of the delithiation effect characteristics.

Optionally, a plurality of actual process parameters are provided, the plurality of actual process parameters including a formation current, a formation temperature, and a cut-off voltage, the preset threshold includes a first threshold and a second threshold that increase in sequence, and determining, when that the deviation is greater than the preset threshold, the to-be-adjusted parameter and the adjustment priority of the to-be-adjusted parameter based on the deviation includes: determining, when that the deviation is greater than the first threshold and less than or equal to the second threshold, the to-be-adjusted parameter to be the formation current and the formation temperature, and determining that the adjustment priority includes priorities of the formation current and the formation temperature decreasing in sequence; and determining, when that the deviation is greater than the second threshold, the to-be-adjusted parameter to be the formation current, the formation temperature, and the cut-off voltage, and determining that the adjustment priority includes priorities of the formation current, the cut-off voltage, and the formation temperature decreasing in sequence.

Optionally, adjusting the formation process based on the to-be-adjusted parameter and the adjustment priority, so that the deviation corresponding to the delithiation effect characteristic quantity after the adjustment is less than or equal to the preset threshold includes: a first determination step of determining the to-be-adjusted parameter with the highest priority to be a target parameter based on the adjustment priority; an adjustment step of adjusting a size of the target parameter based on the deviation and forming the lithium-ion battery by using the adjusted target parameter; a second determination step of determining, when the deviation after the adjustment is greater than the preset threshold, a to-be-adjusted parameter whose priority is after a previous target parameter to be a new target parameter based on the adjustment priority; and a cyclic step of performing the second determination step and the adjustment step cyclically until the deviation after the adjustment is less than or equal to the preset threshold or until the formation process is completed.

Optionally, predicting the delithiation effect characteristic quantity of the lithium replenishing additive in the lithium-ion battery in the formation process based on the actual process parameter includes: building a deep learning model based on artificial intelligence, the deep learning model being trained through machine learning by using a plurality of second data sets, each of the second data sets including: historical process parameters of the formation process and corresponding historical delithiation effect characteristic quantities; and analyzing the actual process parameter by using the deep learning model, and obtaining the delithiation effect characteristic quantity by prediction.

Optionally, acquiring the actual process parameter of the lithium-ion battery in the formation process includes: determining a target process parameter based on a delithiation reaction equation of the lithium replenishing additive, the target process parameter including at least one of a formation current, a cut-off voltage, or a formation temperature; and acquiring an actual value of the target process parameter, and obtaining the actual process parameter.

Optionally, before acquiring the reference range of the delithiation effect characteristics of the lithium replenishing additive, the method further includes: acquiring a capacity curve of the lithium-ion battery in the formation process; and extracting the delithiation effect characteristics including a lithium replenishing agent capacity exertion rate and an actual voltage based on the capacity curve, the lithium replenishing agent capacity exertion rate being a ratio of an actual capacity of the lithium replenishing additive to a theoretical capacity of the lithium replenishing additive.

Optionally, the reference range includes an exertion rate threshold and a voltage threshold, and determining the deviation of the delithiation effect characteristic quantity from the reference range based on the delithiation effect characteristic quantity and the reference range includes: determining a difference between the exertion rate threshold and an actual value of the lithium replenishing agent capacity exertion rate to be a first deviation based on the actual value of the lithium replenishing agent capacity exertion rate and the exertion rate threshold; and determining a difference between a value of the actual voltage and the voltage threshold to be a second deviation based on the value of the actual voltage and the voltage threshold, the first deviation and the second deviation forming the deviation.

Optionally, the exertion rate threshold is 95%, and the voltage threshold is 4.2 V.

According to another aspect of the present disclosure, a formation system for a lithium-ion battery is provided, including: a formation device of the lithium-ion battery configured to perform a formation process for the lithium-ion battery; and a control device of the formation device, including one or more processors, a memory, and one or more programs. The one or more programs are stored in the memory and configured to be executed by the one or more processors. When the one or more programs are executed by the one or more processors, the one or more processors are caused to implement the method in the above aspect.

According to a further aspect of the present disclosure, a non-volatile computer-readable storage medium is provided. The non-volatile computer-readable storage medium stores executable instructions that, when executed by a processor, cause the processor to perform the method in the above aspect.

### BRIEF DESCRIPTION OF THE DRAWINGS

The accompanying drawings forming part of the present disclosure are intended to provide further understanding of the present disclosure. Exemplary embodiments of the present disclosure and descriptions thereof are intended to explain the present disclosure, and do not constitute any inappropriate limitation on the present disclosure. In the drawings,

FIG. 1 is a block diagram illustrating a hardware structure of a mobile terminal performing a formation control method for a lithium-ion battery according to embodiments of the present disclosure;

FIG. 2 is a flow diagram illustrating a formation control method for a lithium-ion battery according to embodiments of the present disclosure; and

FIG. 3 is a structural block diagram illustrating a formation control device for a lithium-ion battery according to embodiments of the present disclosure.

### DETAILED DESCRIPTION

It is to be noted that embodiments in the present disclosure and features in the embodiments may be combined with each other without conflict. The present disclosure will be described in detail below with reference to the accompanying drawings and embodiments.

In order to make those skilled in the art better understand the solutions of the present disclosure, the technical solutions in the embodiments of the present disclosure will be described clearly and completely below with reference to the accompanying drawings in the embodiments of the present disclosure. Apparently, the described embodiments are merely some of rather than all of the embodiments of the present disclosure. All other embodiments acquired by those of ordinary skill in the art without creative efforts based on the embodiments of the present disclosure shall fall within the protection scope of the present disclosure.

It is to be noted that the terms “first”, “second”, and the like in the specification and claims of the present disclosure and the accompanying drawings are used to distinguish similar objects and are not necessarily used to describe a specific order or sequence. It should be understood that data so used may be interchanged where appropriate, to facilitate the embodiments of the present disclosure described herein. In addition, the terms such as “comprise/include”, “have”, and any variants thereof are intended to cover a non-exclusive inclusion, for example, processes, methods, systems, products, or devices including a series of steps or units are not limited to these steps or units listed, and may include other steps or units not listed, or may include other steps or units inherent to these processes, methods, systems, products, or devices.

The technical solutions in the embodiments of the present disclosure will be clearly and completely described below with reference to the accompanying drawings in the embodiments of the present disclosure.

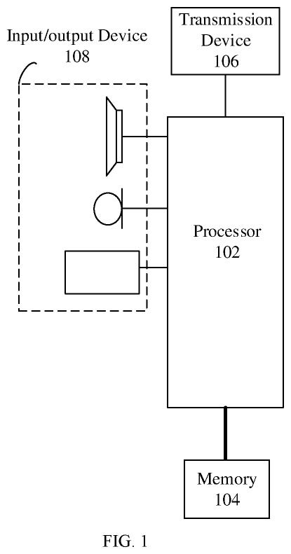

Method embodiments provided in the embodiments of the present disclosure may be executed in a mobile terminal, a computer terminal, or a similar computing apparatus. Based on an example in which the method is performed in a mobile terminal, FIG. 1 is a block diagram illustrating a hardware structure of a mobile terminal for a formation control method for a lithium-ion battery according to embodiments of the present disclosure. As shown in FIG. 1, the mobile terminal may include one or more (only one is shown in FIG. 1) processors 102 (the processors 102 may include, but are not limited to, processing devices such as a microprocessor (MCU) or a programmable logical device (e.g., FPGA)) and a memory 104 configured to store data. The mobile terminal may further include a transmission module 106 for communication functions, and an input/output device 108. Those of ordinary skill in the art may understand that the structure shown in FIG. 1 is only for the purpose of illustration, and is not intend to limit the structure of the mobile terminal. For example, the mobile terminal may alternatively include more or fewer components than those shown in FIG. 1, or have a configuration different from that shown in FIG. 1.

The memory 104 may be configured to store a computer program, for example, software programs and modules of application software such as a computer program corresponding to the formation control method for the lithium-ion battery in the embodiments of the present disclosure. The processor 102 executes the computer program stored in the memory 104 to implement various functional applications and data processing, that is, implement the method. The memory 104 may include a high-speed random access memory (RAM), and may also include a non-volatile memory, for example, one or more magnetic storage apparatuses, flash memories, or other non-volatile solid-state memories. In some examples, the memory 104 may further include memories remotely disposed relative to the processor 102, and these remote memories may be connected to the mobile terminal over a network. Examples of the network include, but are not limited to, the Internet, an intranet, a local area network, a mobile communication network, or a combination thereof. The transmission apparatus 106 is configured to receive or send data over a network. A specific example of the network may include a wireless network provided by a communication provider of the mobile terminal. In an example, the transmission apparatus 106 includes a network interface controller (NIC), which may be connected to another network device through a base station so as to communicate with the Internet. In an embodiment, the transmission apparatus 106 may be a radio frequency (RF) module, which is configured to wirelessly communicate with the Internet.

In this embodiment, a formation control method for a lithium-ion battery running on a mobile terminal, a computer terminal, or a similar computing apparatus is provided. It is to be noted that the steps shown in the flow diagram of the accompanying drawings may be performed, for example, in a computer system with a group of computer executable instructions. In addition, although a logical sequence is shown in the flow diagram, the steps shown or described may be performed in a different sequence than herein.

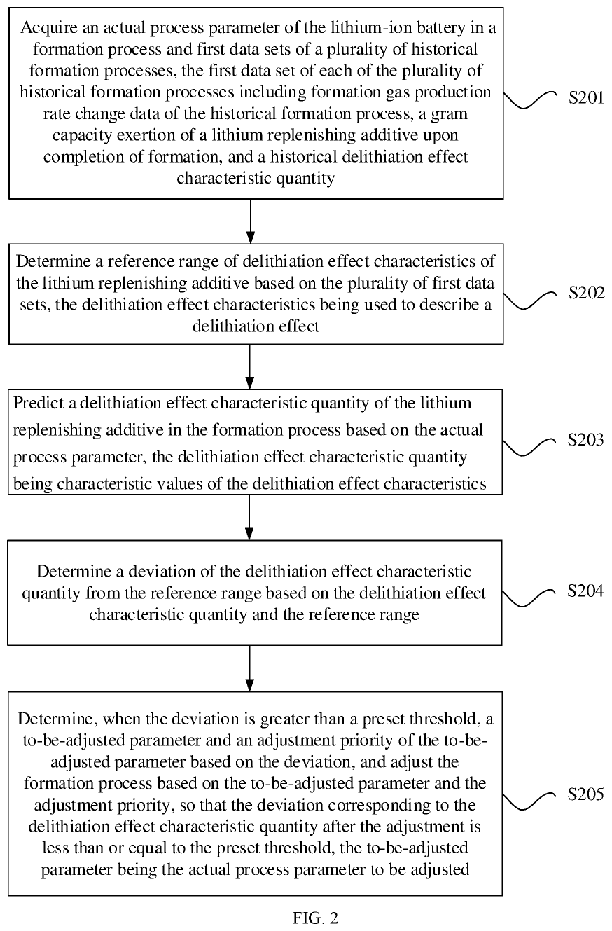

FIG. 2 is a flow diagram illustrating a formation control method for a lithium-ion battery according to embodiments of the present disclosure. As shown in FIG. 2, the method includes the following steps.

In step S201, an actual process parameter of the lithium-ion battery in a formation process and first data sets of a plurality of historical formation processes are acquired, the first data set of each of the plurality of historical formation processes including formation gas production rate change data of the historical formation process, a gram capacity exertion of a lithium replenishing additive upon completion of formation, and a historical delithiation effect characteristic quantity.

Specifically, compared with the plurality of historical formation processes, the formation process may be understood as a present formation process. One of the historical formation processes corresponds to one of the first data sets. The actual process parameter is a process parameter required to be controlled in the formation process. The gram capacity exertion refers to a capacity exerted by each gram of lithium replenishing additive. The historical delithiation effect characteristic quantity refers to characteristic values of the delithiation effect characteristics in the historical formation process.

In step S202, a reference range of delithiation effect characteristics of the lithium replenishing additive is determined based on the plurality of first data sets, the delithiation effect characteristics being used to describe a delithiation effect.

Specifically, the reference range may include only one endpoint value, or may include a value range formed by two endpoint values.

In step S203, a delithiation effect characteristic quantity of the lithium replenishing additive in the formation process is predicted based on the actual process parameter, the delithiation effect characteristic quantity being characteristic values of the delithiation effect characteristics.

In step S204, a deviation of the delithiation effect characteristic quantity from the reference range is determined based on the delithiation effect characteristic quantity and the reference range.

Specifically, the deviation is obtained by comparing the delithiation effect characteristic quantity with the reference range.

In step S205, when the deviation is greater than a preset threshold, a to-be-adjusted parameter and an adjustment priority of the to-be-adjusted parameter are determined based on the deviation, and the formation process is adjusted based on the to-be-adjusted parameter and the adjustment priority, so that the deviation corresponding to the delithiation effect characteristic quantity after the adjustment is less than or equal to the preset threshold, the to-be-adjusted parameter being the actual process parameter to be adjusted.

Specifically, a plurality of to-be-adjusted parameters are obtained based on the deviation, and the adjustment priority is used to represent an order of priorities of the plurality of to-be-adjusted parameters.

In this embodiment, firstly, an actual process parameter of the lithium-ion battery in a formation process and first data sets of a plurality of historical formation processes are acquired. The first data set includes formation gas production rate change data in the historical formation process, a gram capacity exertion of a lithium replenishing additive upon completion of the historical formation process, and a historical delithiation effect characteristic quantity of the historical formation process. Then, a reference range of delithiation effect characteristics of the lithium replenishing additive is determined based on the plurality of first data sets acquired. A delithiation effect characteristic quantity of the lithium replenishing additive in the formation process is predicted based on the actual process parameter; a deviation of the delithiation effect characteristic quantity from the reference range is predicted. Finally, when the deviation is greater than a preset threshold, a to-be-adjusted parameter and an adjustment priority thereof are determined from the actual process parameter based on the deviation, and the formation process is determined based on the to-be-adjusted parameter and the adjustment priority, so that a deviation of the delithiation effect characteristic quantity of the adjusted formation process relative to the reference range is no greater than the preset threshold. In the present disclosure, the reference range of the delithiation effect characteristics is determined based on the data such as the formation gas production rate change data of the historical formation processes, the gram capacity exertion of the lithium replenishing additive upon completion of formation, and the historical delithiation effect characteristic quantities. A delithiation effect characteristic quantity is predicted during the formation of the lithium-ion battery, and the to-be-adjusted parameter during the formation is adjusted based on the adjustment priority based on a deviation of the predicted delithiation effect characteristic quantity from the reference range, so that the deviation after the adjustment is less than the preset threshold, that is, the delithiation effect characteristic quantity after the adjustment relatively fits the reference range of the delithiation effect characteristics, which achieves online adjustment of the delithiation effect of the lithium replenishing additive during the formation of the lithium-ion battery, ensures that the lithium replenishing additive in the formation process has a better release effect and the delithiation effect is more stable and consistent, solves the technical problem of poor stability of the lithium replenishing agent delithiation effect of the battery during the formation, and ensures better consistency of electrical performance of the cells.

In an optional solution, the first data set includes the formation gas production rate change data corresponding to a plurality of historical time nodes in the historical formation process, the gram capacity exertion corresponding to the historical formation process, and historical delithiation effect characteristic quantities corresponding to the plurality of historical time nodes. The plurality of historical time nodes are nodes representing process progress of the corresponding historical formation processes, and step S202 of determining a reference range of delithiation effect characteristics of the lithium replenishing additive based on the plurality of first data sets specifically includes the following steps.

In step S2021, at least one of the historical delithiation effect characteristic quantities corresponding to a first target parameter value at each of the historical time nodes is selected from the plurality of first data sets as a preliminary historical delithiation effect characteristic quantity. The first target parameter value being one of a minimum formation gas production rate change data and a maximum gram capacity exertion.

Specifically, at least one historical delithiation effect characteristic quantity corresponding to the minimum formation gas production rate change data or the maximum gram capacity exertion at each historical time node is selected from the plurality of first data sets as the preliminary historical delithiation effect characteristic quantity. That is, each historical time node corresponds to at least one preliminary historical delithiation effect characteristic quantity.

In step S2022, the preliminary historical delithiation effect characteristic quantity corresponding to a second target parameter value at each of the historical time nodes is determined to be a delithiation effect reference value, and the reference range representing variations of the delithiation effect reference value over time is obtained. The second target parameter value is the other of the minimum formation gas production rate change data and the maximum gram capacity exertion. The delithiation effect reference value is a reference value of the delithiation effect characteristics.

Specifically, a preliminary historical delithiation effect characteristic quantity corresponding to the other of the minimum formation gas production rate change data and the maximum gram capacity exertion is selected from preliminary historical delithiation effect characteristic quantities at each historical time node as a delithiation effect reference value, and the delithiation effect reference value at each historical time node is obtained. When the first target parameter value is the minimum formation gas production rate change data, the second target parameter value is the maximum gram capacity exertion. When the first target parameter value is the maximum gram capacity exertion, the second target parameter value is the minimum formation gas production rate change data.

In this embodiment, based on the principle of maximizing the gram capacity exertion and the most stable formation gas production rate, the delithiation effect characteristic quantity is calibrated based on the gram capacity exertion of the lithium replenishing additive in the historical formation process and the formation gas production rate change data. Specifically, the historical delithiation effect characteristic quantity corresponding to the minimum formation gas production rate change data or the maximum gram capacity exertion at each historical time node is determined from the plurality of first data sets to be the delithiation effect reference value at each historical time node, and an optimal reference range that represents the variations of the delithiation effect reference value over time is obtained, which further ensures that the reference value of the delithiation effect characteristics at each time node can be obtained more accurately.

Specifically, one of the first data sets includes a plurality of pieces of formation gas production rate change data, one gram capacity exertion, and a plurality of historical delithiation effect characteristic quantities. Different first data sets correspond to a same historical time node. For example, the plurality of first data sets each include data corresponding to three historical time nodes: an initial node, an intermediate node, and an end node. In another example, the plurality of first data sets each include data corresponding to the four historical time nodes of 8:00, 8:30, 9:00, and 9:30, and so on. A plurality of time nodes of the actual process parameter and a plurality of historical time nodes of the historical formation process are in one-to-one correspondence.

It is to be noted that in step S2021, if only one preliminary historical delithiation effect characteristic quantity at a historical time node is selected, in step S2022, the delithiation effect reference value at the historical time node is the preliminary historical delithiation effect characteristic quantity. In step S2021, if a plurality of preliminary historical delithiati on effect characteristic quantities at a historical time node are selected, in step S2022, there is a need to select the preliminary historical delithiation effect characteristic quantity corresponding to the second target parameter from the plurality of preliminary historical delithiation effect characteristic quantities at the historical time node as the delithiation effect reference value at the historical time node.

Formation conditions of a plurality of historical formation processes are different, including, but not limited to, charging rates of the lithium-ion battery corresponding to the plurality of historical formation processes being 0.01C (representing that the battery is charged at a rate of 0.01 times a rated capacity thereof per hour), 0.02C (the battery is charged at a rate of 0.02 times the rated capacity thereof per hour), 0.1C (the battery is charged at a rate of 0.1 times the rated capacity thereof per hour), and the like respectively, formation negative pressure being −60 kPa, −70 kPa, −80 kPa, and the like respectively, and formation voltages being 4.0 V, 4.1 V, 4.2 V, and the like respectively.

The formation gas production rate change data may be obtained by acquiring a gas production amount during the formation, then a gas production rate is calculated based on the gas production amount, and a change rate of the gas production rate is calculated.

According to some other exemplary embodiments of the present disclosure, a plurality of actual process parameters are provided. The plurality of actual process parameters include a formation current, a formation temperature, and a cut-off voltage. The preset threshold includes a first threshold and a second threshold that increase in sequence. Determining, when the deviation is greater than the preset threshold, the to-be-adjusted parameter and the adjustment priority of the to-be-adjusted parameter based on the deviation includes: determining, when the deviation is greater than the first threshold and less than or equal to the second threshold, the to-be-adjusted parameter to be the formation current and the formation temperature, and determining that the adjustment priority includes priorities of the formation current and the formation temperature decreasing in sequence; and determining, when the deviation is greater than the preset threshold, the to-be-adjusted parameter to be the formation current, the formation temperature, and the cut-off voltage, and determining that the adjustment priority includes priorities of the formation current, the cut-off voltage, and the formation temperature decreasing in sequence. In this embodiment, based on the size of the deviation, the adjustment of the formation process is divided into two stages. A first adjustment stage is entered when the deviation is greater than the first threshold and not greater than the second threshold. Compared with the reference range, the delithiation effect characteristic quantity at this stage has a small deviation. In this case, the to-be-adjusted parameter is determined to be the formation current and the formation temperature, and it is determined that adjustment is performed based on the adjustment priority of first adjusting the formation current and then adjusting the formation temperature. A second adjustment stage is entered when the deviation is greater than the second threshold. Compared with the reference range, the current delithiation effect characteristic quantity at this stage has a large deviation. In this case, it is determined that the three actual process parameters, namely, the formation current, the formation temperature, and the cut-off voltage, are required to be adjusted, and it is determined that adjustment is performed based on the adjustment priority of first adjusting the formation current, then adjusting the cut-off voltage, and then adjusting the formation temperature. By dividing the adjustment of the formation process into stages and adjusting the formation process based on the to-be-adjusted parameter and the adjustment priority, the deviation can be adjusted efficiently and quickly to a value no greater than the first threshold, which further ensures that the delithiation effect of the formation process is relatively stable and effective and further ensures that consistency of performance of the lithium-ion battery is better.

In order to further realize efficient and rapid adjustment of the deviation of the delithiation effect characteristic quantity to further ensure better stability and consistency of formation and delithiation, in some other optional solutions, adjusting the formation process based on the to-be-adjusted parameter and the adjustment priority, so that the deviation corresponding to the delithiation effect characteristic quantity after the adjustment is less than or equal to the preset threshold includes: a first determination step of determining the to-be-adjusted parameter with the highest priority to be a target parameter based on the adjustment priority; an adjustment step of adjusting a size of the target parameter based on the deviation and forming the lithium-ion battery by using the adjusted target parameter, i.e., increasing or decreasing the size of the target parameter in the formation process; a second determination step of determining, when the deviation after the adjustment is greater than the preset threshold, a to-be-adjusted parameter whose priority is after a previous target parameter to be a new target parameter based on the adjustment priority, the target parameter adjusted in the previous step of the second determination step being the previous target parameter; and a cyclic step of performing the second determination step and the adjustment step cyclically until the deviation after the adjustment is less than or equal to the preset threshold or until the formation process is completed. In this embodiment, based on the adjustment priority, sizes of a plurality of to-be-adjusted parameters in the formation process are adjusted in sequence, and whether the deviation meets a preset threshold requirement is determined after each to-be-adjusted parameter is adjusted. By cyclically adjusting the plurality of to-be-adjusted parameters, closed-loop fine-tuning of the delithiation effect characteristic quantity is achieved until the process of formation is completed, which further ensures a better release effect of the lithium replenishing additive in the formation process and better stability of the delithiation effect.

In an actual application process, those skilled in the art may choose any suitable manner to predict the delithiation effect characteristic quantity based on the actual process parameter of the formation process. In an optional embodiment, predicting the delithiation effect characteristic quantity of the lithium replenishing additive in the lithium-ion battery in the formation process based on the actual process parameter includes: building a deep learning model based on artificial intelligence, the deep learning model being trained through machine learning by using a plurality of second data sets, each of the second data sets including: historical process parameters of the formation process and corresponding historical delithiation effect characteristic quantities; and analyzing the actual process parameter by using the deep learning model, and obtaining the delithiation effect characteristic quantity by prediction. Since the deep learning model based on artificial intelligence has advantages of strong data processing and generalization capabilities, a strong adaptive learning capability, and a low requirement for human intervention, by analyzing the actual process parameter through the deep learning model based on artificial intelligence, the delithiation effect characteristic quantity of the formation process can be predicted, and the delithiation effect characteristic quantity can be obtained automatically and accurately.

Specifically, the deep learning model based on artificial intelligence includes, but is not limited to, machine learning models such as a convolutional neural network (CNN), a recurrent neural network (RNN), a long short-term memory (LSTM) network, a generative adversarial network (GAN), and a deep reinforcement learning network. In addition to the machine learning models, the model may also include a semi-empirical model.

In another optional solution, acquiring the actual process parameter of the lithium-ion battery in the formation process includes: determining a target process parameter based on a delithiation reaction equation of the lithium replenishing additive, the target process parameter including at least one of a formation current, a cut-off voltage, or a formation temperature; and acquiring an actual value of the target process parameter, and obtaining the actual process parameter. Based on a delithiation reaction equation of the lithium replenishing additive, important factors affecting the delithiation effect characteristics during the formation are extracted, the target process parameter including at least part of the formation current, the cut-off voltage, and the formation temperature is obtained, and then a parameter value of the target process parameter is acquired to obtain the actual process parameter including at least part of a formation current value, a cut-off voltage value, and a formation temperature value.

The delithiation reaction equation includes: a first lithium replenishing platform (3.5 to 3.8 V) equation LisFeO₄→Li₃FeO_{3.5}+0.25O₂ (GaS)+2Li⁺2e⁻, and a second lithium replenishing platform (3.9 to 4.1 V) equation Li₃FeO_{3.5}→LiFeO₂+0.75O₂(GaS)+2Li⁺2e⁻.

Optionally, before acquiring the reference range of the delithiation effect characteristics of the lithium replenishing additive, the method further includes: acquiring a capacity curve of the lithium-ion battery in the formation process; and extracting the delithiation effect characteristics including a lithium replenishing agent capacity exertion rate and an actual voltage based on the capacity curve, the lithium replenishing agent capacity exertion rate being a ratio of an actual capacity of the lithium replenishing additive to a theoretical capacity of the lithium replenishing additive, and the actual voltage being an actual formation voltage. In this embodiment, the lithium replenishing agent capacity exertion rate and the actual voltage are obtained based on the capacity curve to represent the delithiation effect characteristics in the formation process, and the delithiation effect characteristics can be accurately represented through the lithium replenishing agent capacity exertion rate and the actual voltage.

In other embodiments, the reference range includes an exertion rate threshold and a voltage threshold, that is, the reference value of the delithiation effect characteristics includes an exertion rate threshold and a voltage threshold, and determining the deviation of the delithiation effect characteristic quantity from the reference range based on the delithiation effect characteristic quantity and the reference range includes: determining a difference between the exertion rate threshold and an actual value of the lithium replenishing agent capacity exertion rate to be a first deviation based on the actual value of the lithium replenishing agent capacity exertion rate and the exertion rate threshold; and determining a difference between a value of the actual voltage and the voltage threshold to be a second deviation based on the value of the actual voltage and the voltage threshold, the first deviation and the second deviation forming the deviation.

Exemplarily, the exertion rate threshold is 95%, and the voltage threshold is 4.2 V. Certainly, in addition to the specific values of the exertion rate threshold and the voltage threshold, those skilled in the art may also flexibly set the specific values according to a design requirement and an actual situation.

A table of comparisons between performance data of the lithium-ion battery obtained with the method according to the present disclosure and the lithium-ion battery obtained through the existing process is shown in Table 1.

TABLE 1

| | Conventional | Method according to the |
|---|---|---|
| Performance data | process | present disclosure |
| Capacity grading | 4% | 1.5% |
| tolerance distribution | | |
| Cycle life 0.5 P 25° C. | 7% capacity fade after | 0 capacity fade after |
| | 2000 cycles | 2000 cycles |
| Fully charged negative | Occasional punctate | Overall golden with no |
| electrode interface | brown spots | abnormalities |

As can be seen from Table 1, compared with the conventional art, the method according to the present disclosure can ensure stability and consistency of formation and delithiation of different lithium-replenished batteries, thereby improving consistency of electrical performance of the cells.

It is to be noted that the steps shown in the flow diagram of the accompanying drawings may be performed, for example, in a computer system with a group of computer executable instructions. In addition, although a logical sequence is shown in the flow diagram, the steps shown or described may be performed in a different sequence than herein.

Embodiments of the present disclosure further provide a formation control device for a lithium-ion battery. It is to be noted that the formation control device for the lithium-ion battery in the embodiments of the present disclosure may be configured to perform the formation control method for the lithium-ion battery provided in the embodiments of the present disclosure. The device is configured to implement the embodiments and preferred implementations, and what has already been described will not be described again. As used below, the term “module” may be a combination of software and/or hardware that implements a predetermined function. Although the apparatus described in the following embodiments is preferably implemented by software, implementation by hardware or a combination of software and hardware is also possible and contemplated.

The formation control device for the lithium-ion battery provided in the embodiments of the present disclosure is described below.

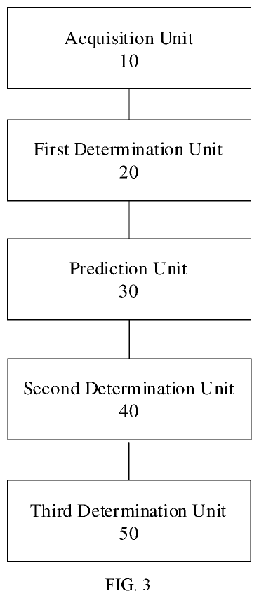

FIG. 3 is a schematic diagram of a formation control device for a lithium-ion battery according to embodiments of the present disclosure. As shown in FIG. 3, the apparatus includes the following units.

An acquisition unit 10 is configured to acquire an actual process parameter of the lithium-ion battery in a formation process and first data sets of a plurality of historical formation processes. The first data set of each of the plurality of historical formation processes includes formation gas production rate change data of the historical formation process, a gram capacity exertion of a lithium replenishing additive upon completion of formation, and a historical delithiation effect characteristic quantity.

Specifically, compared with the plurality of historical formation processes, the formation process may be understood as a present formation process. One of the historical formation processes corresponds to one of the first data sets. The actual process parameter is a process parameter required to be controlled in the formation process. The gram capacity exertion refers to a capacity exerted by each gram of lithium replenishing additive. The historical delithiation effect characteristic quantity refers to characteristic values of the delithiation effect characteristics in the historical formation process.

A first determination unit 20 is configured to determine a reference range of delithiation effect characteristics of the lithium replenishing additive based on the plurality of first data sets. The delithiation effect characteristics are used to describe a delithiation effect.

Specifically, the reference range may include only one endpoint value, or may include a value range formed by two endpoint values.

A prediction unit 30 is configured to predict a delithiation effect characteristic quantity of the lithium replenishing additive in the formation process based on the actual process parameter. The delithiation effect characteristic quantity is characteristic values of the delithiation effect characteristics.

A second determination unit 40 is configured to determine a deviation of the delithiation effect characteristic quantity from the reference range based on the delithiation effect characteristic quantity and the reference range.

Specifically, the deviation is obtained by comparing the delithiation effect characteristic quantity with the reference range.

A third determination unit 50 is configured to determine, when the deviation is greater than a preset threshold, a to-be-adjusted parameter and an adjustment priority of the to-be-adjusted parameter based on the deviation, and adjust the formation process based on the to-be-adjusted parameter and the adjustment priority, so that the deviation corresponding to the delithiation effect characteristic quantity after the adjustment is less than or equal to the preset threshold. The to-be-adjusted parameter is the actual process parameter to be adjusted.

Specifically, a plurality of to-be-adjusted parameters are obtained based on the deviation, and the adjustment priority is used to represent an order of priorities of the plurality of to-be-adjusted parameters.

In this embodiment, an actual process parameter of the lithium-ion battery in a formation process and first data sets of a plurality of historical formation processes are acquired by an acquisition unit. The first data set includes formation gas production rate change data in the historical formation process, a gram capacity exertion of a lithium replenishing additive upon completion of the historical formation process, and a historical delithiation effect characteristic quantity of the historical formation process. A reference range of delithiation effect characteristics of the lithium replenishing additive is determined by a first determination unit based on the plurality of first data sets acquired. A delithiation effect characteristic quantity of the lithium replenishing additive in the formation process is predicted by a prediction unit based on the actual process parameter. A deviation of the delithiation effect characteristic quantity from the reference range is predicted by a second determination unit. When the deviation is greater than a preset threshold, through a third determination unit, a to-be-adjusted parameter and an adjustment priority thereof are determined from the actual process parameter based on the deviation, and the formation process is determined based on the to-be-adjusted parameter and the adjustment priority, so that a deviation of the delithiation effect characteristic quantity of the adjusted formation process relative to the reference range is no greater than the preset threshold. In the present disclosure, the reference range of the delithiation effect characteristics is determined based on the data such as the formation gas production rate change data of the historical formation processes, the gram capacity exertion of the lithium replenishing additive upon completion of formation, and the historical delithiation effect characteristic quantities, a delithiation effect characteristic quantity is predicted during the formation of the lithium-ion battery, and the to-be-adjusted parameter during the formation is adjusted based on the adjustment priority based on a deviation of the predicted delithiation effect characteristic quantity relative to the reference range, so that the deviation after the adjustment is less than the preset threshold, that is, the delithiation effect characteristic quantity after the adjustment relatively fits the reference range of the delithiation effect characteristics, which achieves online adjustment of the delithiation effect of the lithium replenishing additive during the formation of the lithium-ion battery, ensures that the lithium replenishing additive in the formation process has a better release effect and the delithiation effect is more stable and consistent, solves the technical problem of poor stability of the lithium replenishing agent delithiation effect of the battery during the formation, and ensures better consistency of electrical performance of the cells.

The formation control device for the lithium-ion battery includes a processor and a memory. The acquisition unit, the first determination unit, the prediction unit, the second determination unit, and the third determination unit are all stored in the memory as program units, and the processor executes the program units stored in the memory to implement corresponding functions. The modules are all located in a same processor. Alternatively, the modules located in different processors in any combination.

The processor includes a core, and the core retrieves the corresponding program unit from the memory. One or more cores may be provided. At least the problem of poor stability of the lithium replenishing agent delithiation effect of the battery during the formation in the prior art is solved by adjusting parameters of the cores.

The memory may include a volatile memory, a RAM, a non-volatile memory, and/or another form in a computer-readable medium, for example, a read-only memory (ROM) or a flash memory (flash RAM). The memory includes at least one memory chip.

Embodiments of the present disclosure provide a computer-readable storage medium. The computer-readable storage medium includes a program stored therein. When the program is run, a device where the computer-readable storage medium is located is controlled to perform the formation control method for the lithium-ion battery.

Specifically, the formation control method for the lithium-ion battery includes the following steps.

In step S201, an actual process parameter of the lithium-ion battery in a formation process and first data sets of a plurality of historical formation processes are acquired, the first data set of each of the plurality of historical formation processes including formation gas production rate change data of the historical formation process, a gram capacity exertion of a lithium replenishing additive upon completion of formation, and a historical delithiation effect characteristic quantity.

Specifically, compared with the plurality of historical formation processes, the formation process may be understood as a present formation process. One of the historical formation processes corresponds to one of the first data sets. The actual process parameter is a process parameter required to be controlled in the formation process. The gram capacity exertion refers to a capacity exerted by each gram of lithium replenishing additive. The historical delithiation effect characteristic quantity refers to characteristic values of the delithiation effect characteristics in the historical formation process.

In step S202, a reference range of delithiation effect characteristics of the lithium replenishing additive is determined based on the plurality of first data sets, the delithiation effect characteristics being used to describe a delithiation effect.

Specifically, the reference range may include only one endpoint value, or may include a value range formed by two endpoint values.

In step S203, a delithiation effect characteristic quantity of the lithium replenishing additive in the formation process is predicted based on the actual process parameter, the delithiation effect characteristic quantity being characteristic values of the delithiation effect characteristics.

In step S204, a deviation of the delithiation effect characteristic quantity from the reference range is determined based on the delithiation effect characteristic quantity and the reference range.

Specifically, the deviation is obtained by comparing the delithiation effect characteristic quantity with the reference range.

In step S205, when the deviation is greater than a preset threshold, a to-be-adjusted parameter and an adjustment priority of the to-be-adjusted parameter are determined based on the deviation, and the formation process is adjusted based on the to-be-adjusted parameter and the adjustment priority, so that the deviation corresponding to the delithiation effect characteristic quantity after the adjustment is less than or equal to the preset threshold, the to-be-adjusted parameter being the actual process parameter to be adjusted.

Specifically, a plurality of to-be-adjusted parameters are obtained based on the deviation, and the adjustment priority is used to represent an order of priorities of the plurality of to-be-adjusted parameters.

Optionally, the first data set includes the formation gas production rate change data corresponding to a plurality of historical time nodes in the historical formation process, the gram capacity exertion corresponding to the historical formation process, and historical delithiation effect characteristic quantities corresponding to the plurality of historical time nodes, the plurality of historical time nodes being nodes representing process progress of the corresponding historical formation processes, and determining the reference range of delithiation effect characteristics of the lithium replenishing additive based on the plurality of first data sets includes: selecting at least one of the historical delithiation effect characteristic quantities corresponding to a first target parameter value at each of the historical time nodes from the plurality of first data sets as a preliminary historical delithiation effect characteristic quantity, the first target parameter value being one of a minimum formation gas production rate change data and a maximum gram capacity exertion; and determining the preliminary historical delithiation effect characteristic quantity corresponding to a second target parameter value at each of the historical time nodes to be a delithiation effect reference value, and obtaining the reference range representing variations of the delithiation effect reference value over time, the second target parameter value being the other of the minimum formation gas production rate change data and the maximum gram capacity exertion, the delithiation effect reference value being a reference value of the delithiation effect characteristics.

Optionally, a plurality of actual process parameters are provided, the plurality of actual process parameters including a formation current, a formation temperature, and a cut-off voltage, the preset threshold includes a first threshold and a second threshold that increase in sequence, and determining, when the deviation is greater than the preset threshold, the to-be-adjusted parameter and the adjustment priority of the to-be-adjusted parameter based on the deviation includes: determining, when the deviation is greater than the first threshold and less than or equal to the second threshold, the to-be-adjusted parameter to be the formation current and the formation temperature, and determining that the adjustment priority includes priorities of the formation current and the formation temperature decreasing in sequence; and determining, when the deviation is greater than the second threshold, the to-be-adjusted parameter to be the formation current, the formation temperature, and the cut-off voltage, and determining that the adjustment priority includes priorities of the formation current, the cut-off voltage, and the formation temperature decreasing in sequence.

Optionally, adjusting the formation process based on the to-be-adjusted parameter and the adjustment priority, so that the deviation corresponding to the delithiation effect characteristic quantity after the adjustment is less than or equal to the preset threshold includes: a first determination step of determining the to-be-adjusted parameter with the highest priority to be a target parameter based on the adjustment priority; an adjustment step of adjusting a size of the target parameter based on the deviation and forming the lithium-ion battery by using the adjusted target parameter; a second determination step of determining, when the deviation after the adjustment is greater than the preset threshold, a to-be-adjusted parameter whose priority is after a previous target parameter to be a new target parameter based on the adjustment priority; and a cyclic step of performing the second determination step and the adjustment step cyclically until the deviation after the adjustment is less than or equal to the preset threshold or until the formation process is completed.

Optionally, predicting the delithiation effect characteristic quantity of the lithium replenishing additive in the lithium-ion battery in the formation process based on the actual process parameter includes: building a deep learning model based on artificial intelligence, the deep learning model being trained through machine learning by using a plurality of second data sets, each of the second data sets including: historical process parameters of the formation process and corresponding historical delithiation effect characteristic quantities; and analyzing the actual process parameter by using the deep learning model, and obtaining the delithiation effect characteristic quantity by prediction.

Optionally, acquiring the actual process parameter of the lithium-ion battery in the formation process includes: determining a target process parameter based on a delithiation reaction equation of the lithium replenishing additive, the target process parameter including at least one of a formation current, a cut-off voltage, or a formation temperature; and acquiring an actual value of the target process parameter, and obtaining the actual process parameter.

Optionally, before acquiring the reference range of the delithiation effect characteristics of the lithium replenishing additive, the method further includes: acquiring a capacity curve of the lithium-ion battery in the formation process; and extracting the delithiation effect characteristics including a lithium replenishing agent capacity exertion rate and an actual voltage based on the capacity curve, the lithium replenishing agent capacity exertion rate being a ratio of an actual capacity of the lithium replenishing additive to a theoretical capacity of the lithium replenishing additive.

Optionally, the reference range includes an exertion rate threshold and a voltage threshold, and determining the deviation of the delithiation effect characteristic quantity from the reference range based on the delithiation effect characteristic quantity and the reference range includes: determining a difference between the exertion rate threshold and an actual value of the lithium replenishing agent capacity exertion rate to be a first deviation based on the actual value of the lithium replenishing agent capacity exertion rate and the exertion rate threshold; and determining a difference between a value of the actual voltage and the voltage threshold to be a second deviation based on the value of the actual voltage and the voltage threshold, the first deviation and the second deviation forming the deviation.

Optionally, the exertion rate threshold is 95%, and the voltage threshold is 4.2 V.

Embodiments of the present disclosure provide a processor. The processor is configured to run a program. When the program is run, the formation control method for the lithium-ion battery is performed.

Specifically, the formation control method for the lithium-ion battery includes the following steps.

In step S201, an actual process parameter of the lithium-ion battery in a formation process and first data sets of a plurality of historical formation processes are acquired, the first data set of each of the plurality of historical formation processes including formation gas production rate change data of the historical formation process, a gram capacity exertion of a lithium replenishing additive upon completion of formation, and a historical delithiation effect characteristic quantity.

Specifically, compared with the plurality of historical formation processes, the formation process may be understood as a present formation process. One of the historical formation processes corresponds to one of the first data sets. The actual process parameter is a process parameter required to be controlled in the formation process. The gram capacity exertion refers to a capacity exerted by each gram of lithium replenishing additive. The historical delithiation effect characteristic quantity refers to characteristic values of the delithiation effect characteristics in the historical formation process.

In step S202, a reference range of delithiation effect characteristics of the lithium replenishing additive is determined based on the plurality of first data sets, the delithiation effect characteristics being used to describe a delithiation effect.

Specifically, the reference range may include only one endpoint value, or may include a value range formed by two endpoint values.

In step S203, a delithiation effect characteristic quantity of the lithium replenishing additive in the formation process is predicted based on the actual process parameter, the delithiation effect characteristic quantity being characteristic values of the delithiation effect characteristics.

In step S204, a deviation of the delithiation effect characteristic quantity from the reference range is determined based on the delithiation effect characteristic quantity and the reference range.

Specifically, the deviation is obtained by comparing the delithiation effect characteristic quantity with the reference range.

In step S205, when the deviation is greater than a preset threshold, a to-be-adjusted parameter and an adjustment priority of the to-be-adjusted parameter are determined based on the deviation, and the formation process is adjusted based on the to-be-adjusted parameter and the adjustment priority, so that the deviation corresponding to the delithiation effect characteristic quantity after the adjustment is less than or equal to the preset threshold, the to-be-adjusted parameter being the actual process parameter to be adjusted.

Specifically, a plurality of to-be-adjusted parameters are obtained based on the deviation, and the adjustment priority is used to represent an order of priorities of the plurality of to-be-adjusted parameters.

Optionally, the first data set includes the formation gas production rate change data corresponding to a plurality of historical time nodes in the historical formation process, the gram capacity exertion corresponding to the historical formation process, and historical delithiation effect characteristic quantities corresponding to the plurality of historical time nodes, the plurality of historical time nodes being nodes representing process progress of the corresponding historical formation processes, and determining the reference range of delithiation effect characteristics of the lithium replenishing additive based on the plurality of first data sets includes: selecting at least one of the historical delithiation effect characteristic quantities corresponding to a first target parameter value at each of the historical time nodes from the plurality of first data sets as a preliminary historical delithiation effect characteristic quantity, the first target parameter value being one of a minimum formation gas production rate change data and a maximum gram capacity exertion; and determining the preliminary historical delithiation effect characteristic quantity corresponding to a second target parameter value at each of the historical time nodes to be a delithiation effect reference value, and obtaining the reference range representing variations of the delithiation effect reference value over time, the second target parameter value being the other of the minimum formation gas production rate change data and the maximum gram capacity exertion, the delithiation effect reference value being a reference value of the delithiation effect characteristics.

Optionally, a plurality of actual process parameters are provided, the plurality of actual process parameters including a formation current, a formation temperature, and a cut-off voltage, the preset threshold includes a first threshold and a second threshold that increase in sequence, and determining, when the deviation is greater than the preset threshold, the to-be-adjusted parameter and the adjustment priority of the to-be-adjusted parameter based on the deviation includes: determining, when the deviation is greater than the first threshold and less than or equal to the second threshold, the to-be-adjusted parameter to be the formation current and the formation temperature, and determining that the adjustment priority includes priorities of the formation current and the formation temperature decreasing in sequence; and determining, when the deviation is greater than the second threshold, the to-be-adjusted parameter to be the formation current, the formation temperature, and the cut-off voltage, and determining that the adjustment priority includes priorities of the formation current, the cut-off voltage, and the formation temperature decreasing in sequence.

Optionally, adjusting the formation process based on the to-be-adjusted parameter and the adjustment priority, so that the deviation corresponding to the delithiation effect characteristic quantity after the adjustment is less than or equal to the preset threshold includes: a first determination step of determining the to-be-adjusted parameter with the highest priority to be a target parameter based on the adjustment priority; an adjustment step of adjusting a size of the target parameter based on the deviation and forming the lithium-ion battery by using the adjusted target parameter; a second determination step of determining, when the deviation after the adjustment is greater than the preset threshold, a to-be-adjusted parameter whose priority is after a previous target parameter to be a new target parameter based on the adjustment priority; and a cyclic step of performing the second determination step and the adjustment step cyclically until the deviation after the adjustment is less than or equal to the preset threshold or until the formation process is completed.

Optionally, predicting the delithiation effect characteristic quantity of the lithium replenishing additive in the lithium-ion battery in the formation process based on the actual process parameter includes: building a deep learning model based on artificial intelligence, the deep learning model being trained through machine learning by using a plurality of second data sets, each of the second data sets including: historical process parameters of the formation process and corresponding historical delithiation effect characteristic quantities; and analyzing the actual process parameter by using the deep learning model, and obtaining the delithiation effect characteristic quantity by prediction.

Optionally, acquiring the actual process parameter of the lithium-ion battery in the formation process includes: determining a target process parameter based on a delithiation reaction equation of the lithium replenishing additive, the target process parameter including at least one of a formation current, a cut-off voltage, or a formation temperature; and acquiring an actual value of the target process parameter, and obtaining the actual process parameter.

Optionally, before acquiring the reference range of the delithiation effect characteristics of the lithium replenishing additive, the method further includes: acquiring a capacity curve of the lithium-ion battery in the formation process; and extracting the delithiation effect characteristics including a lithium replenishing agent capacity exertion rate and an actual voltage based on the capacity curve, the lithium replenishing agent capacity exertion rate being a ratio of an actual capacity of the lithium replenishing additive to a theoretical capacity of the lithium replenishing additive.

Optionally, the reference range includes an exertion rate threshold and a voltage threshold, and determining the deviation of the delithiation effect characteristic quantity from the reference range based on the delithiation effect characteristic quantity and the reference range includes: determining a difference between the exertion rate threshold and an actual value of the lithium replenishing agent capacity exertion rate to be a first deviation based on the actual value of the lithium replenishing agent capacity exertion rate and the exertion rate threshold; and determining a difference between a value of the actual voltage and the voltage threshold to be a second deviation based on the value of the actual voltage and the voltage threshold, the first deviation and the second deviation forming the deviation.

Optionally, the exertion rate threshold is 95%, and the voltage threshold is 4.2 V.

Embodiments of the present disclosure provide a formation system for a lithium-ion battery, including: a formation device of the lithium-ion battery configured to perform a formation process for the lithium-ion battery; and a control device of the formation device, including one or more processors, a memory, and one or more programs. The one or more programs are stored in the memory and configured to be executed by the one or more processors. The one or more processors, when executing the one or more programs, implement at least the following steps.

In step S201, an actual process parameter of the lithium-ion battery in a formation process and first data sets of a plurality of historical formation processes are acquired, the first data set of each of the plurality of historical formation processes including formation gas production rate change data of the historical formation process, a gram capacity exertion of a lithium replenishing additive upon completion of formation, and a historical delithiation effect characteristic quantity.

Specifically, compared with the plurality of historical formation processes, the formation process may be understood as a present formation process. One of the historical formation processes corresponds to one of the first data sets. The actual process parameter is a process parameter required to be controlled in the formation process. The gram capacity exertion refers to a capacity exerted by each gram of lithium replenishing additive. The historical delithiation effect characteristic quantity refers to characteristic values of the delithiation effect characteristics in the historical formation process.

In step S202, a reference range of delithiation effect characteristics of the lithium replenishing additive is determined based on the plurality of first data sets, the delithiation effect characteristics being used to describe a delithiation effect.

Specifically, the reference range may include only one endpoint value, or may include a value range formed by two endpoint values.

In step S203, a delithiation effect characteristic quantity of the lithium replenishing additive in the formation process is predicted based on the actual process parameter, the delithiation effect characteristic quantity being characteristic values of the delithiation effect characteristics.

In step S204, a deviation of the delithiation effect characteristic quantity from the reference range is determined based on the delithiation effect characteristic quantity and the reference range.

Specifically, the deviation is obtained by comparing the delithiation effect characteristic quantity with the reference range.

In step S205, when the deviation is greater than a preset threshold, a to-be-adjusted parameter and an adjustment priority of the to-be-adjusted parameter are determined based on the deviation, and the formation process is adjusted based on the to-be-adjusted parameter and the adjustment priority, so that the deviation corresponding to the delithiation effect characteristic quantity after the adjustment is less than or equal to the preset threshold, the to-be-adjusted parameter being the actual process parameter to be adjusted.

Specifically, a plurality of to-be-adjusted parameters are obtained based on the deviation, and the adjustment priority is used to represent an order of priorities of the plurality of to-be-adjusted parameters.

In the formation system for the lithium-ion battery, a formation process for the lithium-ion battery is performed by a formation device, and the formation control method for the lithium-ion battery is performed by a control device. In the method, the reference range of the delithiation effect characteristics is determined based on the data such as the formation gas production rate change data of the historical formation processes, the gram capacity exertion of the lithium replenishing additive upon completion of formation, and the historical delithiation effect characteristic quantities, a delithiation effect characteristic quantity is predicted during the formation of the lithium-ion battery, and the to-be-adjusted parameter during the formation is adjusted based on the adjustment priority based on a deviation of the predicted delithiation effect characteristic quantity relative to the reference range, so that the deviation after the adjustment is less than the preset threshold, that is, the delithiation effect characteristic quantity after the adjustment relatively fits the reference range of the delithiation effect characteristics, which achieves online adjustment of the delithiation effect of the lithium replenishing additive during the formation of the lithium-ion battery, ensures that the lithium replenishing additive in the formation process has a better release effect and the delithiation effect is more stable and consistent, solves the technical problem of poor stability of the lithium replenishing agent delithiation effect of the battery during the formation, and ensures better consistency of electrical performance of the cells.

The control device herein may be a server, a PC, a PAD, a mobile phone, or the like.

Optionally, the first data set includes the formation gas production rate change data corresponding to a plurality of historical time nodes in the historical formation process, the gram capacity exertion corresponding to the historical formation process, and historical delithiation effect characteristic quantities corresponding to the plurality of historical time nodes, the plurality of historical time nodes being nodes representing process progress of the corresponding historical formation processes, and determining the reference range of delithiation effect characteristics of the lithium replenishing additive based on the plurality of first data sets includes: selecting at least one of the historical delithiation effect characteristic quantities corresponding to a first target parameter value at each of the historical time nodes from the plurality of first data sets as a preliminary historical delithiation effect characteristic quantity, the first target parameter value being one of a minimum formation gas production rate change data and a maximum gram capacity exertion; and determining the preliminary historical delithiation effect characteristic quantity corresponding to a second target parameter value at each of the historical time nodes to be a delithiation effect reference value, and obtaining the reference range representing variations of the delithiation effect reference value over time, the second target parameter value being the other of the minimum formation gas production rate change data and the maximum gram capacity exertion, the delithiation effect reference value being a reference value of the delithiation effect characteristics.

Optionally, a plurality of actual process parameters are provided, the plurality of actual process parameters including a formation current, a formation temperature, and a cut-off voltage, the preset threshold includes a first threshold and a second threshold that increase in sequence, and determining, when the deviation is greater than the preset threshold, the to-be-adjusted parameter and the adjustment priority of the to-be-adjusted parameter based on the deviation includes: determining, when the deviation is greater than the first threshold and less than or equal to the second threshold, the to-be-adjusted parameter to be the formation current and the formation temperature, and determining that the adjustment priority includes priorities of the formation current and the formation temperature decreasing in sequence; and determining, when the deviation is greater than the second threshold, the to-be-adjusted parameter to be the formation current, the formation temperature, and the cut-off voltage, and determining that the adjustment priority includes priorities of the formation current, the cut-off voltage, and the formation temperature decreasing in sequence.

Optionally, adjusting the formation process based on the to-be-adjusted parameter and the adjustment priority, so that the deviation corresponding to the delithiation effect characteristic quantity after the adjustment is less than or equal to the preset threshold includes: a first determination step of determining the to-be-adjusted parameter with the highest priority to be a target parameter based on the adjustment priority; an adjustment step of adjusting a size of the target parameter based on the deviation and forming the lithium-ion battery by using the adjusted target parameter; a second determination step of determining, when the deviation after the adjustment is greater than the preset threshold, a to-be-adjusted parameter whose priority is after a previous target parameter to be a new target parameter based on the adjustment priority; and a cyclic step of performing the second determination step and the adjustment step cyclically until the deviation after the adjustment is less than or equal to the preset threshold or until the formation process is completed.

Optionally, predicting the delithiation effect characteristic quantity of the lithium replenishing additive in the lithium-ion battery in the formation process based on the actual process parameter includes: building a deep learning model based on artificial intelligence, the deep learning model being trained through machine learning by using a plurality of second data sets, each of the second data sets including: historical process parameters of the formation process and corresponding historical delithiation effect characteristic quantities; and analyzing the actual process parameter by using the deep learning model, and obtaining the delithiation effect characteristic quantity by prediction.

Optionally, acquiring the actual process parameter of the lithium-ion battery in the formation process includes: determining a target process parameter based on a delithiation reaction equation of the lithium replenishing additive, the target process parameter including at least one of a formation current, a cut-off voltage, or a formation temperature; and acquiring an actual value of the target process parameter, and obtaining the actual process parameter.

Optionally, before acquiring the reference range of the delithiation effect characteristics of the lithium replenishing additive, the method further includes: acquiring a capacity curve of the lithium-ion battery in the formation process; and extracting the delithiation effect characteristics including a lithium replenishing agent capacity exertion rate and an actual voltage based on the capacity curve, the lithium replenishing agent capacity exertion rate being a ratio of an actual capacity of the lithium replenishing additive to a theoretical capacity of the lithium replenishing additive.

Optionally, the reference range includes an exertion rate threshold and a voltage threshold, and determining the deviation of the delithiation effect characteristic quantity from the reference range based on the delithiation effect characteristic quantity and the reference range includes: determining a difference between the exertion rate threshold and an actual value of the lithium replenishing agent capacity exertion rate to be a first deviation based on the actual value of the lithium replenishing agent capacity exertion rate and the exertion rate threshold; and determining a difference between a value of the actual voltage and the voltage threshold to be a second deviation based on the value of the actual voltage and the voltage threshold, the first deviation and the second deviation forming the deviation.

Optionally, the exertion rate threshold is 95%, and the voltage threshold is 4.2 V.

The present disclosure further provides a computer program product, including computer instructions. When the computer instructions are executed by a processor, at least programs of the following method steps are implemented.

In step S201, an actual process parameter of the lithium-ion battery in a formation process and first data sets of a plurality of historical formation processes are acquired, the first data set of each of the plurality of historical formation processes including formation gas production rate change data of the historical formation process, a gram capacity exertion of a lithium replenishing additive upon completion of formation, and a historical delithiation effect characteristic quantity.

In step S202, a reference range of delithiation effect characteristics of the lithium replenishing additive is determined based on the plurality of first data sets, the delithiation effect characteristics being used to describe a delithiation effect.

In step S203, a delithiation effect characteristic quantity of the lithium replenishing additive in the formation process is predicted based on the actual process parameter, the delithiation effect characteristic quantity being characteristic values of the delithiation effect characteristics.

In step S204, a deviation of the delithiation effect characteristic quantity from the reference range is determined based on the delithiation effect characteristic quantity and the reference range.

In step S205, when the deviation is greater than a preset threshold, a to-be-adjusted parameter and an adjustment priority of the to-be-adjusted parameter are determined based on the deviation, and the formation process is adjusted based on the to-be-adjusted parameter and the adjustment priority, so that the deviation corresponding to the delithiation effect characteristic quantity after the adjustment is less than or equal to the preset threshold, the to-be-adjusted parameter being the actual process parameter to be adjusted.

Optionally, the first data set includes the formation gas production rate change data corresponding to a plurality of historical time nodes in the historical formation process, the gram capacity exertion corresponding to the historical formation process, and historical delithiation effect characteristic quantities corresponding to the plurality of historical time nodes, the plurality of historical time nodes being nodes representing process progress of the corresponding historical formation processes, and determining the reference range of delithiation effect characteristics of the lithium replenishing additive based on the plurality of first data sets includes: selecting at least one of the historical delithiation effect characteristic quantities corresponding to a first target parameter value at each of the historical time nodes from the plurality of first data sets as a preliminary historical delithiation effect characteristic quantity, the first target parameter value being one of a minimum formation gas production rate change data and a maximum gram capacity exertion; and determining the preliminary historical delithiation effect characteristic quantity corresponding to a second target parameter value at each of the historical time nodes to be a delithiation effect reference value, and obtaining the reference range representing variations of the delithiation effect reference value over time, the second target parameter value being the other of the minimum formation gas production rate change data and the maximum gram capacity exertion, the delithiation effect reference value being a reference value of the delithiation effect characteristics.

Optionally, a plurality of actual process parameters are provided, the plurality of actual process parameters including a formation current, a formation temperature, and a cut-off voltage, the preset threshold includes a first threshold and a second threshold that increase in sequence, and determining, when the deviation is greater than the preset threshold, the to-be-adjusted parameter and the adjustment priority of the to-be-adjusted parameter based on the deviation includes: determining, when the deviation is greater than the first threshold and less than or equal to the second threshold, the to-be-adjusted parameter to be the formation current and the formation temperature, and determining that the adjustment priority includes priorities of the formation current and the formation temperature decreasing in sequence; and determining, when the deviation is greater than the second threshold, the to-be-adjusted parameter to be the formation current, the formation temperature, and the cut-off voltage, and determining that the adjustment priority includes priorities of the formation current, the cut-off voltage, and the formation temperature decreasing in sequence.

Optionally, adjusting the formation process based on the to-be-adjusted parameter and the adjustment priority, so that the deviation corresponding to the delithiation effect characteristic quantity after the adjustment is less than or equal to the preset threshold includes: a first determination step of determining the to-be-adjusted parameter with the highest priority to be a target parameter based on the adjustment priority; an adjustment step of adjusting a size of the target parameter based on the deviation and forming the lithium-ion battery by using the adjusted target parameter; a second determination step of determining, when the deviation after the adjustment is greater than the preset threshold, a to-be-adjusted parameter whose priority is after a previous target parameter to be a new target parameter based on the adjustment priority; and a cyclic step of performing the second determination step and the adjustment step cyclically until the deviation after the adjustment is less than or equal to the preset threshold or until the formation process is completed.

Optionally, predicting the delithiation effect characteristic quantity of the lithium replenishing additive in the lithium-ion battery in the formation process based on the actual process parameter includes: building a deep learning model based on artificial intelligence, the deep learning model being trained through machine learning by using a plurality of second data sets, each of the second data sets including: historical process parameters of the formation process and corresponding historical delithiation effect characteristic quantities; and analyzing the actual process parameter by using the deep learning model, and obtaining the delithiation effect characteristic quantity by prediction.

Optionally, acquiring the actual process parameter of the lithium-ion battery in the formation process includes: determining a target process parameter based on a delithiation reaction equation of the lithium replenishing additive, the target process parameter including at least one of a formation current, a cut-off voltage, or a formation temperature; and acquiring an actual value of the target process parameter, and obtaining the actual process parameter.

Optionally, before acquiring the reference range of the delithiation effect characteristics of the lithium replenishing additive, the method further includes: acquiring a capacity curve of the lithium-ion battery in the formation process; and extracting the delithiation effect characteristics including a lithium replenishing agent capacity exertion rate and an actual voltage based on the capacity curve, the lithium replenishing agent capacity exertion rate being a ratio of an actual capacity of the lithium replenishing additive to a theoretical capacity of the lithium replenishing additive.

Optionally, the reference range includes an exertion rate threshold and a voltage threshold, and determining the deviation of the delithiation effect characteristic quantity from the reference range based on the delithiation effect characteristic quantity and the reference range includes: determining a difference between the exertion rate threshold and an actual value of the lithium replenishing agent capacity exertion rate to be a first deviation based on the actual value of the lithium replenishing agent capacity exertion rate and the exertion rate threshold; and determining a difference between a value of the actual voltage and the voltage threshold to be a second deviation based on the value of the actual voltage and the voltage threshold, the first deviation and the second deviation forming the deviation.

Optionally, the exertion rate threshold is 95%, and the voltage threshold is 4.2 V.

Apparently, it is to be understood by those skilled in the art that the modules or steps of the present disclosure may be implemented by a general-purpose computing apparatus and may be concentrated on a single computing apparatus or distributed in a network formed by a plurality of computing apparatuses, which may be implemented using program code executable by the computing apparatuses. Therefore, these modules or steps may be stored in a storage apparatus and executed by the computing apparatus. Moreover, in some cases, the illustrated or described steps may be executed in a sequence different from the sequence described herein. Alternatively, each of these modules or steps may be implemented by being made into an integrated circuit module or a plurality of these modules or steps may be implemented by being made into a single integrated circuit module. In this way, the present disclosure is not limited to any specific combination of hardware and software.

Those skilled in the art should understand that the embodiments of the present disclosure may be provided as a method, a system, or a computer program product. Therefore, the present disclosure may take a form of hardware only embodiments, software only embodiments, or embodiments with a combination of software and hardware. Moreover, the present disclosure may use a form of a computer program product that is implemented on one or more computer-usable storage media (including, but not limited to, a disk memory, a CD-ROM, an optical memory, and the like) that include computer-usable program code.

The present disclosure is described with reference to the flow diagrams and/or block diagrams of the method, the device (system), and the computer program product according to the embodiments of the present disclosure. It should be understood that computer program instructions may be used to implement each process and/or each block in the flow diagrams and/or the block diagrams and a combination of a process and/or a block in the flow diagrams and/or the block diagrams. These computer program instructions may be provided for a general-purpose computer, a dedicated computer, an embedded processor, or a processor of any other programmable data processing device to generate a machine, so that the instructions executed by a computer or a processor of any other programmable data processing device generate an apparatus for implementing a specific function in one or more processes in the flow diagrams and/or in one or more blocks in the block diagrams.

These computer program instructions may also be stored in a computer-readable memory that can instruct the computer or any other programmable data processing device to operate in a specific manner, so that the instructions stored in the computer-readable memory generate an artifact that includes an instruction apparatus. The instruction apparatus implements a specific function in one or more processes in the flow diagrams and/or in one or more blocks in the block diagrams.

These computer program instructions may be loaded onto a computer or another programmable data processing device, so that a series of operations and steps are performed on the computer or the another programmable device, thereby generating computer-implemented processing. Therefore, the instructions executed on the computer or the another programmable device provide steps for implementing a specific function in one or more processes in the flow diagrams and/or in one or more blocks in the block diagrams.

In a typical configuration, a computing device includes one or more processors (CPUs), an input/output interface, a network interface, and a memory.

The memory may include a volatile memory, a RAM, a non-volatile memory, and/or another form in a computer-readable medium, for example, a ROM or a flash memory (flash RAM). The memory is an example of the computer-readable medium.

The computer-readable medium includes non-volatile, volatile, removable and non-removable media that can implement information storage by using any method or technology. Information may be a computer-readable instruction, a data structure, a program module, or other data. An example of a computer storage medium includes, but is not limited to, a phase-change random access memory (PRAM), a static random access memory (SRAM), a dynamic random access memory (DRAM), another type of RAM, a ROM, an electrically erasable programmable read-only memory (EEPROM), a flash memory or another memory technology, a compact disc read-only memory (CD-ROM), a digital versatile disc (DVD) or another optical storage, a cassette magnetic tape, a tape and disk storage or another magnetic storage device or any other non-transmission media that may be configured to store information accessible to the computing device. As described in the present application, the computer-readable medium does not include computer-readable transitory media such as a modulated data signal and a carrier.

Embodiments of the present disclosure provide a non-volatile computer-readable storage medium. The non-volatile computer-readable storage medium stores executable instructions that, when executed by a processor, cause the processor to perform the method described in the above embodiments.

It is to be further noted that the terms such as “comprise”, “include”, or any other variants thereof are intended to cover a non-exclusive inclusion, so that a process, method, commodity, or device including a list of elements includes not only those elements but also other elements not expressly listed or that are inherent to the process, method, commodity, or device. Without more limitations, an element defined by the statement “including a/an . . . ” does not exclude the presence of additional identical elements in the process, method, good, or device that includes the element.

As can be seen from the above description, the embodiments described in the present disclosure achieve the following technical effects.

1). In the formation control method for the lithium-ion battery according to the present disclosure, firstly, an actual process parameter of the lithium-ion battery in a formation process and first data sets of a plurality of historical formation processes are acquired. The first data set includes formation gas production rate change data in the historical formation process, a gram capacity exertion of a lithium replenishing additive upon completion of the historical formation process, and a historical delithiation effect characteristic quantity of the historical formation process. Then, a reference range of delithiation effect characteristics of the lithium replenishing additive is determined based on the plurality of first data sets acquired. A delithiation effect characteristic quantity of the lithium replenishing additive in the formation process is predicted based on the actual process parameter. A deviation of the delithiation effect characteristic quantity from the reference range is predicted. And finally, when the deviation is greater than a preset threshold, a to-be-adjusted parameter and an adjustment priority thereof are determined from the actual process parameter based on the deviation, and the formation process is determined based on the to-be-adjusted parameter and the adjustment priority, so that a deviation of the delithiation effect characteristic quantity of the adjusted formation process relative to the reference range is no greater than the preset threshold. In the present disclosure, the reference range of the delithiation effect characteristics is determined based on the data such as the formation gas production rate change data of the historical formation processes, the gram capacity exertion of the lithium replenishing additive upon completion of formation, and the historical delithiation effect characteristic quantities, a delithiation effect characteristic quantity is predicted during the formation of the lithium-ion battery, and the to-be-adjusted parameter during the formation is adjusted based on the adjustment priority based on a deviation of the predicted delithiation effect characteristic quantity relative to the reference range, so that the deviation after the adjustment is less than the preset threshold, that is, the delithiation effect characteristic quantity after the adjustment relatively fits the reference range of the delithiation effect characteristics, which achieves online adjustment of the delithiation effect of the lithium replenishing additive during the formation of the lithium-ion battery, ensures that the lithium replenishing additive in the formation process has a better release effect and the delithiation effect is more stable and consistent, solves the technical problem of poor stability of the lithium replenishing agent delithiation effect of the battery during the formation, and ensures better consistency of electrical performance of the cells.

2). In the formation system for the lithium-ion battery according to the present disclosure, a formation process for the lithium-ion battery is performed by a formation device, and the formation control method for the lithium-ion battery is performed by a control device. In the method, the reference range of the delithiation effect characteristics is determined based on the data such as the formation gas production rate change data of the historical formation processes, the gram capacity exertion of the lithium replenishing additive upon completion of formation, and the historical delithiation effect characteristic quantities, a delithiation effect characteristic quantity is predicted during the formation of the lithium-ion battery, and the to-be-adjusted parameter during the formation is adjusted based on the adjustment priority based on a deviation of the predicted delithiation effect characteristic quantity relative to the reference range, so that the deviation after the adjustment is less than the preset threshold, that is, the delithiation effect characteristic quantity after the adjustment relatively fits the reference range of the delithiation effect characteristics, which achieves online adjustment of the delithiation effect of the lithium replenishing additive during the formation of the lithium-ion battery, ensures that the lithium replenishing additive in the formation process has a better release effect and the delithiation effect is more stable and consistent, solves the technical problem of poor stability of the lithium replenishing agent delithiation effect of the battery during the formation, and ensures better consistency of electrical performance of the cells.

The above are merely embodiments of the present disclosure and are not intended to limit the present disclosure. For those skilled in the art, various modifications and changes may be made to the present disclosure. Any modifications, equivalent replacements, improvements, and the like made within the spirit and principles of the present disclosure shall be included in the scope of the claims of the present disclosure.

What is claimed is:

1. A formation control method for a lithium-ion battery, the method comprising:
acquiring an actual process parameter of the lithium-ion battery in a formation process and first data sets of a plurality of historical formation processes, the first data set of each of the plurality of historical formation processes comprising formation gas production rate change data of the historical formation process, a gram capacity exertion of a lithium replenishing additive upon completion of formation, and a historical delithiation effect characteristic quantity;
determining a reference range of delithiation effect characteristics of the lithium replenishing additive based on the plurality of first data sets, the delithiation effect characteristics being used to describe a delithiation effect;
predicting a delithiation effect characteristic quantity of the lithium replenishing additive in the formation process based on the actual process parameter, the delithiation effect characteristic quantity being characteristic values of the delithiation effect characteristics;
determining a deviation of the delithiation effect characteristic quantity from the reference range based on the delithiation effect characteristic quantity and the reference range; and
determining, when the deviation is greater than a preset threshold, a to-be-adjusted parameter and an adjustment priority of the to-be-adjusted parameter based on the deviation, and adjusting the formation process based on the to-be-adjusted parameter and the adjustment priority, so that the deviation corresponding to the delithiation effect characteristic quantity after the adjustment is less than or equal to the preset threshold, the to-be-adjusted parameter being the actual process parameter to be adjusted.

2. The formation control method of claim 1, wherein the first data set comprises the formation gas production rate change data corresponding to a plurality of historical time nodes in the historical formation process, the gram capacity exertion corresponding to the historical formation process, and historical delithiation effect characteristic quantities corresponding to the plurality of historical time nodes, the plurality of historical time nodes being nodes representing process progress of the corresponding historical formation processes, and determining the reference range of delithiation effect characteristics of the lithium replenishing additive based on the plurality of first data sets comprises:
selecting at least one of the historical delithiation effect characteristic quantities corresponding to a first target parameter value at each of the historical time nodes from the plurality of first data sets as a preliminary historical delithiation effect characteristic quantity, the first target parameter value being one of a minimum formation gas production rate change data and a maximum gram capacity exertion; and
determining the preliminary historical delithiation effect characteristic quantity corresponding to a second target parameter value at each of the historical time nodes to be a delithiation effect reference value, and obtaining the reference range representing variations of the delithiation effect reference value over time, the second target parameter value being the other of the minimum formation gas production rate change data and the maximum gram capacity exertion, the delithiation effect reference value being a reference value of the delithiation effect characteristics.

3. The formation control method of claim 1, wherein a plurality of actual process parameters are provided, the plurality of actual process parameters comprising a formation current, a formation temperature, and a cut-off voltage, the preset threshold comprises a first threshold and a second threshold that increase in sequence, and determining, when the deviation is greater than the preset threshold, the to-be-adjusted parameter and the adjustment priority of the to-be-adjusted parameter based on the deviation comprises:
determining, when the deviation is greater than the first threshold and less than or equal to the second threshold, the to-be-adjusted parameter to be the formation current and the formation temperature, and determining that the adjustment priority comprises priorities of the formation current and the formation temperature decreasing in sequence; and
determining, when the deviation is greater than the second threshold, the to-be-adjusted parameter to be the formation current, the formation temperature, and the cut-off voltage, and determining that the adjustment priority comprises priorities of the formation current, the cut-off voltage, and the formation temperature decreasing in sequence.

4. The formation control method of claim 2, wherein adjusting the formation process based on the to-be-adjusted parameter and the adjustment priority, so that the deviation corresponding to the delithiation effect characteristic quantity after the adjustment is less than or equal to the preset threshold comprises:
a first determination step of determining the to-be-adjusted parameter with the highest priority to be a target parameter based on the adjustment priority;
an adjustment step of adjusting a size of the target parameter based on the deviation and forming the lithium-ion battery by using the adjusted target parameter;
a second determination step of determining, when the deviation after the adjustment is greater than the preset threshold, a to-be-adjusted parameter whose priority is after a previous target parameter to be a new target parameter based on the adjustment priority; and
a cyclic step of performing the second determination step and the adjustment step cyclically until the deviation after the adjustment is less than or equal to the preset threshold or until the formation process is completed.

5. The formation control method of claim 1, wherein predicting the delithiation effect characteristic quantity of the lithium replenishing additive in the lithium-ion battery in the formation process based on the actual process parameter comprises:
building a deep learning model based on artificial intelligence, the deep learning model being trained through machine learning by using a plurality of second data sets, each of the second data sets comprising historical process parameters of the formation process and corresponding historical delithiation effect characteristic quantities; and
analyzing the actual process parameter by using the deep learning model, and obtaining the delithiation effect characteristic quantity by prediction.

6. The formation control method of claim 1, wherein acquiring the actual process parameter of the lithium-ion battery in the formation process comprises:
determining a target process parameter based on a delithiation reaction equation of the lithium replenishing additive, the target process parameter comprising at least one of a formation current, a cut-off voltage, or a formation temperature; and
acquiring an actual value of the target process parameter, and obtaining the actual process parameter.

7. The formation control method of claim 1, wherein before acquiring the reference range of the delithiation effect characteristics of the lithium replenishing additive, the method further comprises:
acquiring a capacity curve of the lithium-ion battery in the formation process; and
extracting the delithiation effect characteristics comprising a lithium replenishing agent capacity exertion rate and an actual voltage based on the capacity curve, the lithium replenishing agent capacity exertion rate being a ratio of an actual capacity of the lithium replenishing additive to a theoretical capacity of the lithium replenishing additive.

8. The formation control method of claim 7, wherein the reference range comprises an exertion rate threshold and a voltage threshold, and determining the deviation of the delithiation effect characteristic quantity from the reference range based on the delithiation effect characteristic quantity and the reference range comprises:
determining a difference between the exertion rate threshold and an actual value of the lithium replenishing agent capacity exertion rate to be a first deviation based on the actual value of the lithium replenishing agent capacity exertion rate and the exertion rate threshold; and
determining a difference between a value of the actual voltage and the voltage threshold to be a second deviation based on the value of the actual voltage and the voltage threshold, the first deviation and the second deviation forming the deviation.

9. The formation control method of claim 8, wherein the exertion rate threshold is 95%, and the voltage threshold is 4.2 V.

10. A formation system for a lithium-ion battery, comprising:
a formation device of the lithium-ion battery configured to perform a formation process for the lithium-ion battery; and
a control device of the formation device, comprising one or more processors, a memory, and one or more programs, wherein the one or more programs are stored in the memory and configured to be executed by the one or more processors, and when the one or more programs are executed by the one or more processors, the one or more processors are caused to implement:
acquiring an actual process parameter of the lithium-ion battery in a formation process and first data sets of a plurality of historical formation processes, the first data set of each of the plurality of historical formation processes comprising formation gas production rate change data of the historical formation process, a gram capacity exertion of a lithium replenishing additive upon completion of formation, and a historical delithiation effect characteristic quantity;
determining a reference range of delithiation effect characteristics of the lithium replenishing additive based on the plurality of first data sets, the delithiation effect characteristics being used to describe a delithiation effect;
predicting a delithiation effect characteristic quantity of the lithium replenishing additive in the formation process based on the actual process parameter, the delithiation effect characteristic quantity being characteristic values of the delithiation effect characteristics;
determining a deviation of the delithiation effect characteristic quantity from the reference range based on the delithiation effect characteristic quantity and the reference range; and
determining, when the deviation is greater than a preset threshold, a to-be-adjusted parameter and an adjustment priority of the to-be-adjusted parameter based on the deviation, and adjusting the formation process based on the to-be-adjusted parameter and the adjustment priority, so that the deviation corresponding to the delithiation effect characteristic quantity after the adjustment is less than or equal to the preset threshold, the to-be-adjusted parameter being the actual process parameter to be adjusted.

11. The formation system of claim 10, wherein the first data set comprises the formation gas production rate change data corresponding to a plurality of historical time nodes in the historical formation process, the gram capacity exertion corresponding to the historical formation process, and historical delithiation effect characteristic quantities corresponding to the plurality of historical time nodes, the plurality of historical time nodes being nodes representing process progress of the corresponding historical formation processes, and determining the reference range of delithiation effect characteristics of the lithium replenishing additive based on the plurality of first data sets comprises:
selecting at least one of the historical delithiation effect characteristic quantities corresponding to a first target parameter value at each of the historical time nodes from the plurality of first data sets as a preliminary historical delithiation effect characteristic quantity, the first target parameter value being one of a minimum formation gas production rate change data and a maximum gram capacity exertion; and
determining the preliminary historical delithiation effect characteristic quantity corresponding to a second target parameter value at each of the historical time nodes to be a delithiation effect reference value, and obtaining the reference range representing variations of the delithiation effect reference value over time, the second target parameter value being the other of the minimum formation gas production rate change data and the maximum gram capacity exertion, the delithiation effect reference value being a reference value of the delithiation effect characteristics.

12. The formation system of claim 10, wherein a plurality of actual process parameters are provided, the plurality of actual process parameters comprising a formation current, a formation temperature, and a cut-off voltage, the preset threshold comprises a first threshold and a second threshold that increase in sequence, and determining, when the deviation is greater than the preset threshold, the to-be-adjusted parameter and the adjustment priority of the to-be-adjusted parameter based on the deviation comprises:
determining, when the deviation is greater than the first threshold and less than or equal to the second threshold, the to-be-adjusted parameter to be the formation current and the formation temperature, and determining that the adjustment priority comprises priorities of the formation current and the formation temperature decreasing in sequence; and
determining, when the deviation is greater than the second threshold, the to-be-adjusted parameter to be the formation current, the formation temperature, and the cut-off voltage, and determining that the adjustment priority comprises priorities of the formation current, the cut-off voltage, and the formation temperature decreasing in sequence.

13. The formation system of claim 11, wherein adjusting the formation process based on the to-be-adjusted parameter and the adjustment priority, so that the deviation corresponding to the delithiation effect characteristic quantity after the adjustment is less than or equal to the preset threshold comprises:
a first determination step of determining the to-be-adjusted parameter with the highest priority to be a target parameter based on the adjustment priority;
an adjustment step of adjusting a size of the target parameter based on the deviation and forming the lithium-ion battery by using the adjusted target parameter;
a second determination step of determining, when the deviation after the adjustment is greater than the preset threshold, a to-be-adjusted parameter whose priority is after a previous target parameter to be a new target parameter based on the adjustment priority; and
a cyclic step of performing the second determination step and the adjustment step cyclically until the deviation after the adjustment is less than or equal to the preset threshold or until the formation process is completed.

14. The formation system of claim 10, wherein predicting the delithiation effect characteristic quantity of the lithium replenishing additive in the lithium-ion battery in the formation process based on the actual process parameter comprises:
building a deep learning model based on artificial intelligence, the deep learning model being trained through machine learning by using a plurality of second data sets, each of the second data sets comprising historical process parameters of the formation process and corresponding historical delithiation effect characteristic quantities; and
analyzing the actual process parameter by using the deep learning model, and obtaining the delithiation effect characteristic quantity by prediction.

15. The formation system of claim 10, wherein acquiring the actual process parameter of the lithium-ion battery in the formation process comprises:
determining a target process parameter based on a delithiation reaction equation of the lithium replenishing additive, the target process parameter comprising at least one of a formation current, a cut-off voltage, or a formation temperature; and
acquiring an actual value of the target process parameter, and obtaining the actual process parameter.

16. The formation system of claim 10, wherein before acquiring the reference range of the delithiation effect characteristics of the lithium replenishing additive, the one or more processors are further caused to implement:
acquiring a capacity curve of the lithium-ion battery in the formation process; and
extracting the delithiation effect characteristics comprising a lithium replenishing agent capacity exertion rate and an actual voltage based on the capacity curve, the lithium replenishing agent capacity exertion rate being a ratio of an actual capacity of the lithium replenishing additive to a theoretical capacity of the lithium replenishing additive.

17. The formation system of claim 16, wherein the reference range comprises an exertion rate threshold and a voltage threshold, and determining the deviation of the delithiation effect characteristic quantity from the reference range based on the delithiation effect characteristic quantity and the reference range comprises:
determining a difference between the exertion rate threshold and an actual value of the lithium replenishing agent capacity exertion rate to be a first deviation based on the actual value of the lithium replenishing agent capacity exertion rate and the exertion rate threshold; and
determining a difference between a value of the actual voltage and the voltage threshold to be a second deviation based on the value of the actual voltage and the voltage threshold, the first deviation and the second deviation forming the deviation.

18. The formation system of claim 17, wherein the exertion rate threshold is 95%, and the voltage threshold is 4.2 V.

19. A non-volatile computer-readable storage medium storing executable instructions that, when executed by a processor, cause the processor to perform:
acquiring an actual process parameter of the lithium-ion battery in a formation process and first data sets of a plurality of historical formation processes, the first data set of each of the plurality of historical formation processes comprising formation gas production rate change data of the historical formation process, a gram capacity exertion of a lithium replenishing additive upon completion of formation, and a historical delithiation effect characteristic quantity;
determining a reference range of delithiation effect characteristics of the lithium replenishing additive based on the plurality of first data sets, the delithiation effect characteristics being used to describe a delithiation effect;
predicting a delithiation effect characteristic quantity of the lithium replenishing additive in the formation process based on the actual process parameter, the delithiation effect characteristic quantity being characteristic values of the delithiation effect characteristics;
determining a deviation of the delithiation effect characteristic quantity from the reference range based on the delithiation effect characteristic quantity and the reference range; and
determining, when the deviation is greater than a preset threshold, a to-be-adjusted parameter and an adjustment priority of the to-be-adjusted parameter based on the deviation, and adjusting the formation process based on the to-be-adjusted parameter and the adjustment priority, so that the deviation corresponding to the delithiation effect characteristic quantity after the adjustment is less than or equal to the preset threshold, the to-be-adjusted parameter being the actual process parameter to be adjusted.

20. The non-volatile computer-readable storage medium of claim 19, wherein the first data set comprises the formation gas production rate change data corresponding to a plurality of historical time nodes in the historical formation process, the gram capacity exertion corresponding to the historical formation process, and historical delithiation effect characteristic quantities corresponding to the plurality of historical time nodes, the plurality of historical time nodes being nodes representing process progress of the corresponding historical formation processes, and determining the reference range of delithiation effect characteristics of the lithium replenishing additive based on the plurality of first data sets comprises:
selecting at least one of the historical delithiation effect characteristic quantities corresponding to a first target parameter value at each of the historical time nodes from the plurality of first data sets as a preliminary historical delithiation effect characteristic quantity, the first target parameter value being one of a minimum formation gas production rate change data and a maximum gram capacity exertion; and
determining the preliminary historical delithiation effect characteristic quantity corresponding to a second target parameter value at each of the historical time nodes to be a delithiation effect reference value, and obtaining the reference range representing variations of the delithiation effect reference value over time, the second target parameter value being the other of the minimum formation gas production rate change data and the maximum gram capacity exertion, the delithiation effect reference value being a reference value of the delithiation effect characteristics.
